(19) United States
(12) Patent Application Publication
(10) Pub. No.: US 2010/0237439 A1
(43) Pub. Date: Sep. 23, 2010

(54) HIGH-VOLTAGE METAL-DIELECTRIC-SEMICONDUCTOR DEVICE AND METHOD OF THE SAME

(76) Inventors: Ming-Cheng Lee, Hsinchu County (TW); Wei-Li Tsao, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/406,926

(22) Filed: Mar. 18, 2009

(51) Int. Cl. H01L 29/78

(52) U.S. Cl. 257/408; 257/E29.266

(57) ABSTRACT

A high-voltage metal-dielectric-semiconductor transistor includes a semiconductor substrate; a trench isolation region in the semiconductor substrate surrounding an active area; a gate overlying the active area; a drain doping region of a first conductivity type in the active area; a source doping region of the first conductivity type in a first well of a second conductivity type in the active area; and a source lightly doped region of the first conductivity type between the gate and the source doping region; wherein no isolation is formed between the gate and the drain doping region.

### BACKGROUND OF THE INVENTION

1. Field of the Invention

The present invention relates to a high-voltage device structure. More particularly, the present invention relates to a high-voltage metal-dielectric-semiconductor device structure with improved time dependent dielectric breakdown (TDDB) characteristic and reduced hot carrier injection (HCl) effect.

2. Description of the Prior Art

High-voltage metal-dielectric-semiconductors are devices for use under high voltages, which may be, but not limited to, voltages higher than the voltage supplied to the I/O circuit. High-voltage metal-dielectric-semiconductor devices may function as switches and are broadly utilized in audio output drivers, CPU power supplies, power management systems, AC/DC converters, LCD or plasma television drivers, automobile electronic components, PC peripheral devices, small DC motor controllers, and other consumer electronic devices.

FIG. 1 is a schematic, cross-sectional view of a conventional high-voltage N-type metal-dielectric-semiconductor device. As shown in FIG. 1, the high-voltage N-type metal-dielectric-semiconductor device 101 includes a gate 210 overlying an area of a P type substrate 100, a deep N well (DNW) 110 formed in the substrate 100, an N well 120 formed in the substrate 100 proximate a first edge 210a of the gate 210 and doped with a first concentration of an N type dopant, and a channel region 130 doped with a first concentration of a P type dopant underlying a portion of the gate 210 adjacent the N well 120.

Shallow trench isolation (STI) region 1 60 is formed in the first portion of the N well 120. An N⁺ tap region 150 is adjacent to the second portion of the N well 120 distal from the first edge 210a of the gate 210. An N type source region 155 including an N⁺ region and an N type lightly doped region 155b is formed in the P well 140 proximate a second edge 210b of the gate 210 opposite to the first edge 210a.

The N⁺ tap region 150 is formed between the STI region 160 and the STI region 162. The N⁺ tap region 150 is not self-aligned with the gate 210 but is separated from the gate 210 by a distance D. The above-described high-voltage N-type metal-dielectric-semiconductor device 101 utilizes STI region 160 to drop drain voltage and makes high drain sustained voltage. Besides, the above-described high-voltage N-type metal-dielectric-semiconductor device 101 uses well implant to form drain terminal. The above-described high-voltage N-type metal-dielectric-semiconductor device 101 occupies a large surface area on a chip because of the offset STI region. Further, the driving current of such device may be insufficient.

It is desirable to provide a high-voltage metal-dielectric-semiconductor device that can sustain at least 5V at the drain terminal based on a 2.5V device process or below. It is also desirable to provide a high-voltage metal-dielectric-semiconductor device based on a 2.5V device process or below, which is CMOS-compatible and occupies relatively smaller chip real estate. It is also desirable to provide a high-voltage metal-dielectric-semiconductor device based on a 2.5V device process or below, which has increased driving current.

### SUMMARY OF THE INVENTION

It is one objective of the invention to provide a high-voltage metal-dielectric-semiconductor device based on 2.5V process or below, which can sustain at least 5V at the drain terminal.

It is another objective of the invention to provide a high-voltage metal-dielectric-semiconductor device based on 2.5V process or below, which has increased dielectric lifetime and reduced hot carrier injection (HCl) effect.

It is yet another objective of the invention to provide a high-voltage metal-dielectric-semiconductor device based on 2.5V process or below, which is CMOS-compatible and occupies relatively smaller chip real estate.

To these ends, according to one aspect of the present invention, there is provided a high-voltage metal-dielectric-semiconductor transistor including a semiconductor substrate; a trench isolation region in the semiconductor substrate surrounding an active area; a gate overlying the active area; a drain doping region of a first conductivity type in the active area; a source doping region of the first conductivity type in a first well of a second conductivity type in the active area; and a source lightly doped region of the first conductivity type between the gate and the source doping region; wherein no isolation is formed between the gate and the drain doping region.

From another aspect of the invention, a high-voltage metal-dielectric-semiconductor transistor includes a semiconductor substrate; a trench isolation region in the semiconductor substrate surrounding an active area; a gate overlying the active area; a drain doping region of a first conductivity type in a bulk portion of the semiconductor substrate, wherein the semiconductor substrate is of a second conductivity type; a drain lightly doped region of the first conductivity type in the bulk portion of the semiconductor substrate between the gate and the drain doping region; a source doping region of the first conductivity type in a well of the second conductivity type; and a source lightly doped region of the first conductivity type between the gate and the source doping region; wherein no isolation is formed between the gate and the drain doping region.

From still another aspect of the invention, a high-voltage metal-dielectric-semiconductor transistor includes a semiconductor substrate; a trench isolation region in the semiconductor substrate surrounding an active area; a gate overlying the active area; a drain doping region of a first conductivity type in a first well of the first conductivity type, wherein no isolation is formed within the first well, the semiconductor substrate is of a second conductivity type; a source doping region of the first conductivity type in a second well of the second conductivity type; and a source lightly doped region of the first conductivity type between the gate and the source doping region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional diagram illustrating a conventional high-voltage N-type metal-dielectric-semiconductor device.

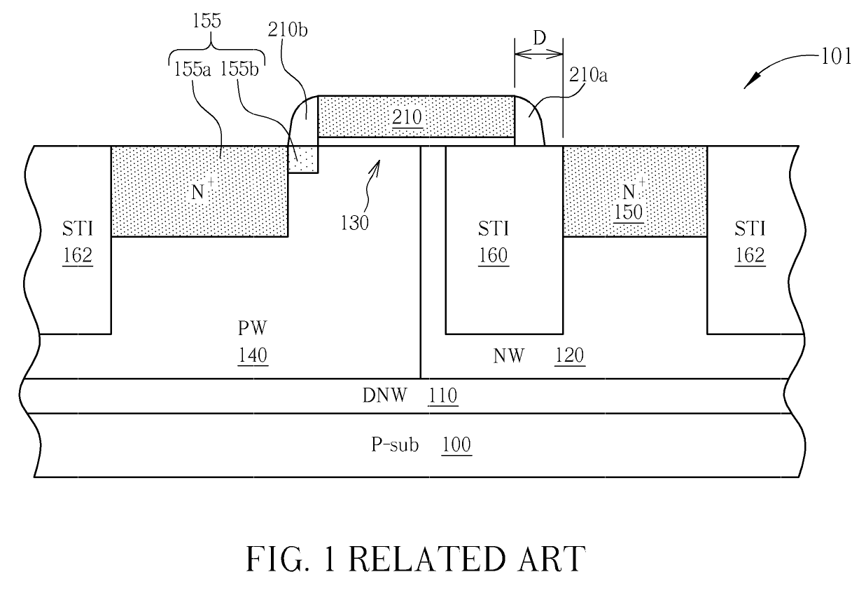

FIG. 2 is an exemplary layout of the improved high-voltage N-type metal-dielectric-semiconductor transistor structure in accordance with one embodiment of this invention.

FIG. 3 is a schematic, cross-sectional view taken alone line I-I′ of FIG. 2.

FIG. 4 is a schematic, cross-sectional diagram showing a high-voltage N-type metal-dielectric-semiconductor transistor structure in accordance with another embodiment of this invention.

FIG. 5 is a schematic, cross-sectional diagram showing a high-voltage N-type metal-dielectric-semiconductor transistor structure in accordance with yet another embodiment of this invention.

FIG. 6 illustrates a variant of the high-voltage N-type metal-dielectric-semiconductor transistor structure of FIG. 5.

FIG. 7 is a schematic, cross-sectional diagram showing a high-voltage N-type metal-dielectric-semiconductor transistor structure in accordance with yet another embodiment of this invention.

FIG. 8 is a variant of the high-voltage N-type metal-dielectric-semiconductor transistor structure of FIG. 7.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the invention.

The exemplary structures of the high-voltage metal-dielectric-semiconductor transistor structures according to the present invention are described in detail. The exemplary high-voltage metal-dielectric-semiconductor transistor structures are described for a high-voltage N-type metal-dielectric-semiconductor transistor, but it should be understood by those skilled in the art that by reversing the polarity of the conductive dopants high-voltage P-type metal-dielectric-semiconductor transistors can be made.

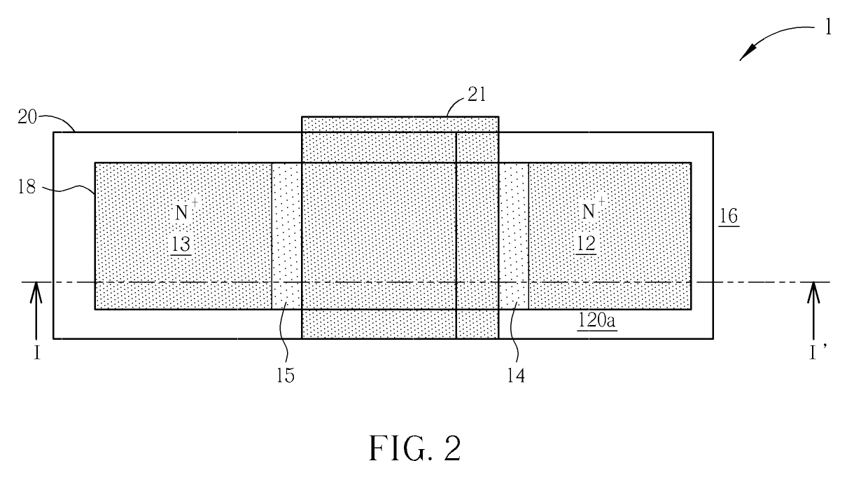

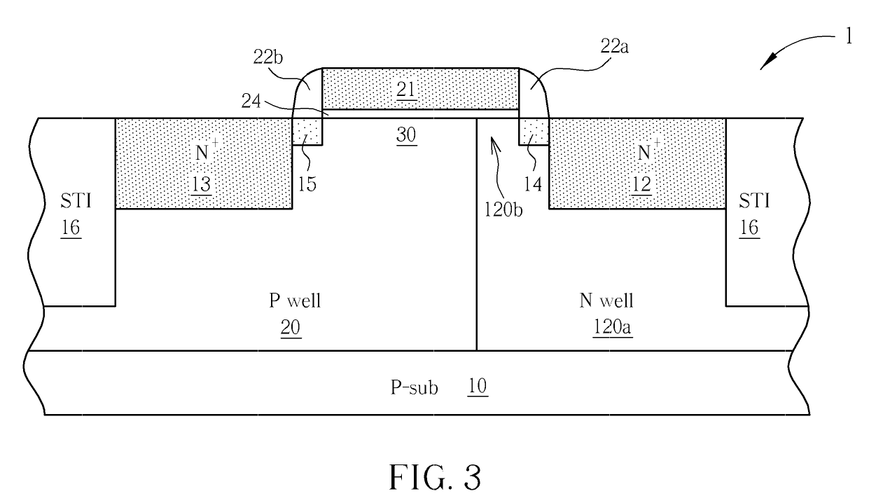

FIG. 2 is an exemplary layout of the improved high-voltage N-type metal-dielectric-semiconductor transistor structure in accordance with one embodiment of this invention. FIG. 3 is a schematic, cross-sectional view taken alone line I-I′ of FIG. 2. As shown in FIGS. 2 and 3, the high-voltage N-type metal-dielectric-semiconductor transistor 1 is formed in an active area or oxide defined (OD) area 18 that is surrounded by shallow trench isolation (STI) region 16. The high-voltage N-type metal-dielectric-semiconductor transistor 1 comprises a gate 21 overlying the active area 18. The gate 21 may comprise polysilicon, metal or silicide.

An N⁺ drain doping region 12 is provided on one side of the gate 21 within the active area 18. According to this embodiment, the N⁺ drain doping region 12 may be formed within an N well 120a. An N type lightly doped drain (NLDD) 14 may be disposed between the gate 21 and the N⁺ drain doping region 12. The NLDD 14 may extend laterally underneath a sidewall spacer 22a that may be formed on a sidewall of the gate 21. The N well 120a includes a well region 120b that is situated under the gate 21. In some embodiments, the well region 120b may be directly under the gate 21. It is one feature of this invention that no STI structure is formed between the N⁺ drain doping region 12 and the gate 21. Omitting the STI region may help increase the driving current and save chip area. The N⁺ drain doping region 12 in conjunction with the NLDD 14 may be referred to as a drain region. In this case, one feature of this invention is that no STI structure is formed in the gate/drain overlap region, which is the region the gate 21 overlaps the drain region.

According to this embodiment, the N⁺ drain doping region 12 may be implanted self-aligned with the edge of the sidewall spacer 22a. On the other side of the gate 21, an N⁺ source doping region 13 may be implanted into a P well 20 within the active area 18. An NLDD 15 may be provided underneath the sidewall spacer 22b opposite to the sidewall spacer 22a. A channel region 30 may be defined under the gate 21 between the NLDD 15 and the well region 120b. A gate dielectric layer 24 such as silicon dioxide, HF oxide, high-k dielectrics, etc. is formed between the gate 21 and the channel region 30.

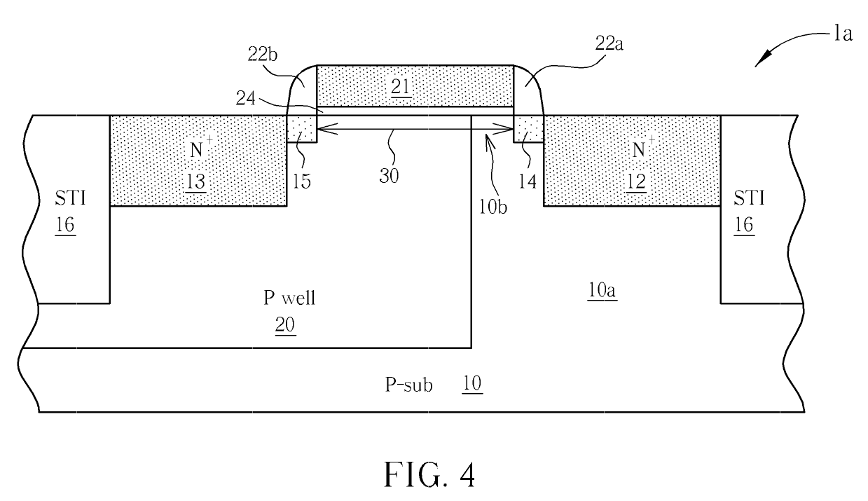

FIG. 4 is a schematic, cross-sectional diagram showing a high-voltage N-type metal-dielectric-semiconductor transistor structure in accordance with another embodiment of this invention. As shown in FIG. 4, the high-voltage N-type metal-dielectric-semiconductor transistor 1 a may be similar to the N-type metal-dielectric-semiconductor transistor structure 1 of FIG. 3 except for that the N⁺ drain doping region 12 and the NLDD 14 are not formed in an N well. Instead, the N⁺ drain doping region 12 and the NLDD 14 of the high-voltage N-type metal-dielectric-semiconductor transistor 1 a are formed in a bulk portion 10a of the P substrate 10. The bulk portion 10a of the P substrate 10 includes an overlapping region 10b that is situated under the gate 21. In some embodiments, the overlapping region 10b may be directly under the gate 21. Omitting the N well may help reduce the HCl effect.

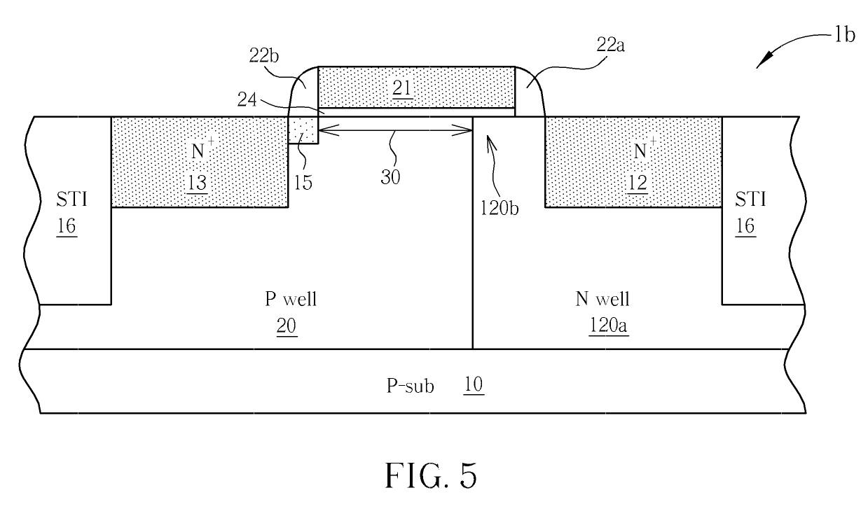

FIG. 5 is a schematic, cross-sectional diagram showing a high-voltage N-type metal-dielectric-semiconductor transistor structure in accordance with yet another embodiment of this invention. As shown in FIG. 5, the high-voltage N-type metal-dielectric-semiconductor transistor 1b may be similar to the N-type metal-dielectric-semiconductor transistor structure 1 of FIG. 3 except for that the NLDD 14 is omitted in FIG. 5. Since the drain dopant concentration at the gate/drain overlap region is reduced, the TDDB characteristic may be improved and the voltage drop in drain depletion region may be increased.

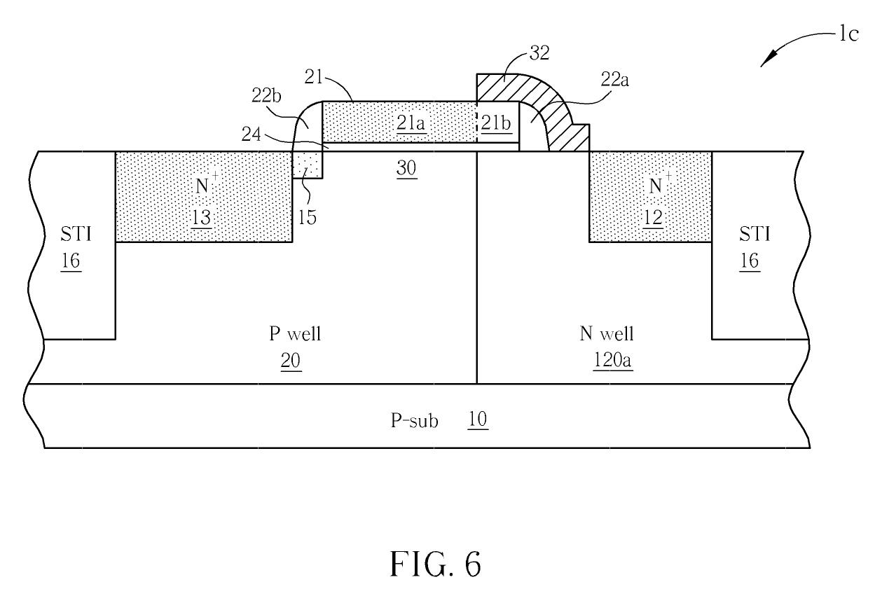

FIG. 6 illustrates a variant of the high-voltage N-type metal-dielectric-semiconductor transistor structure of FIG. 5. As shown in FIG. 6, a source/drain (S/D) implant blocking layer 32 may be applied on the gate 21 and extends to the N well 120a. During the heavy ion implant of the source and drain, the S/D implant blocking layer 32 may mask the portion of the gate 21 proximate to the drain terminal and a portion of the N well 120a, thereby forming an N⁺ drain doping region 12 that is pulled back away from the edge of the gate 21. As indicated in FIG. 6, the drain doping region 12 is not aligned with the edge of the sidewall spacer 22a. Since the gate 21 may be masked during the heavy ion implant of the source and drain, the gate 21 can be divided into two portions 21a and 21b, wherein the non-masked portion 21a has a first concentration of N type dopants that is higher than the second concentration of N type dopants of the masked portion 21b. In addition, the high-voltage N-type metal-dielectric-semiconductor transistor 1c of FIG. 6 may not have an NLDD at the drain side (the NLDD 14 in FIG. 3 is omitted) and may only have an NLDD 15 at its source side.

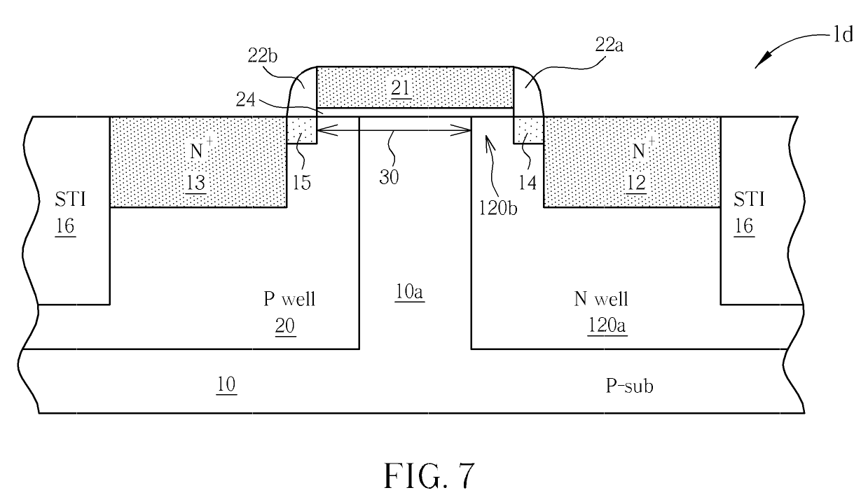

FIG. 7 is a schematic, cross-sectional diagram showing a high-voltage N-type metal-dielectric-semiconductor transistor structure in accordance with yet another embodiment of this invention. As shown in FIG. 7, the high-voltage N-type metal-dielectric-semiconductor transistor 1d may be similar to the N-type metal-dielectric-semiconductor transistor structure 1 of FIG. 3. The difference between the high-voltage N-type metal-dielectric-semiconductor transistor 1 of FIG. 3 and the high-voltage N-type metal-dielectric-semiconductor transistor 1d of FIG. 7 may be that the channel region 30 between the NLDD 15 and the N well 120a may comprise a bulk portion 10a of the P substrate 10. The P well 20 may be separated from the N well 120a by the bulk portion 10a. In doing so, the hot carrier injection (HCl) may be reduced, while the adequate voltage drop at the drain terminal can be maintained.

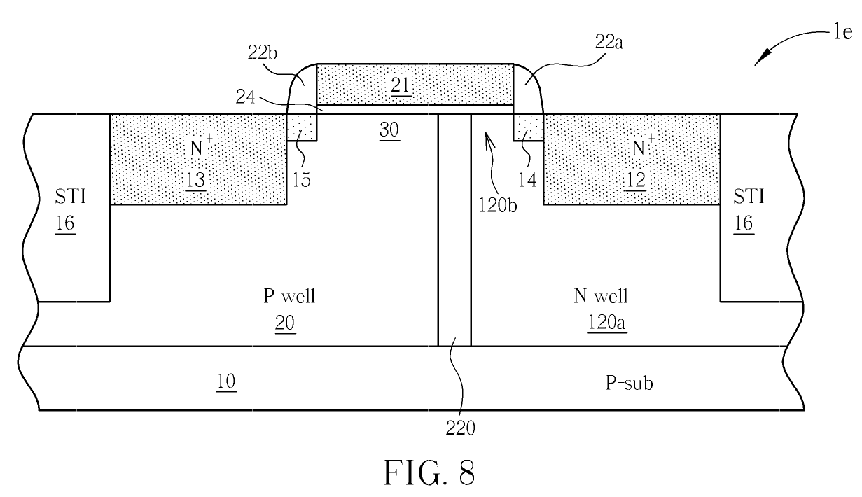

FIG. 8 is a variant of the high-voltage N-type metal-dielectric-semiconductor transistor structure of FIG. 7. As shown in FIG. 8, the high-voltage N-type metal-dielectric-semiconductor transistor 1e may comprise a Pwell 20 that overlaps with the N well 120a to form an intrinsic region 220 located under the gate 21. In some embodiments, the intrinsic region 220 may be directly under the gate 21. Both of the N type dopants and P type dopants may be implanted into the intrinsic region 220 during the N/P well implant process. The intrinsic region 220 between the P well 20 and the N well 120a may help reduce HCl effect.

To sump up, the invention at least include the following features.
(i) The exemplary high-voltage metal-dielectric-semiconductor transistors according to the present invention may be compatible with standard CMOS processes and no additional cost is required.
(ii) The exemplary high-voltage metal-dielectric-semiconductor transistors according to the present invention may be capable of sustaining at least 5V at its terminal based on 2.5V device process or below.
(iii) The TDDB characteristic of the exemplary high-voltage metal-dielectric-semiconductor transistors according to the present invention may be improved by drain dopant concentration engineering.
(iv) The HCl effect in the exemplary high-voltage metal-dielectric-semiconductor transistors according to the present invention may be reduced by drain/bulk junction engineering.
(v) The omitting STI region in the exemplary high-voltage metal-dielectric-semiconductor transistors according to the present invention may increase the driving current and save chip area.

Those skilled in the art will readily observe that numerous modifications and alterations of the device and method may be made while retaining the teachings of the invention.

What is claimed is:

1. A high-voltage metal-dielectric-semiconductor transistor, comprising:
a semiconductor substrate;
a trench isolation region in the semiconductor substrate surrounding an active area;
a gate overlying the active area;
a drain doping region of a first conductivity type in the active area;
a source doping region of the first conductivity type in a first well of a second conductivity type in the active area; and
a source lightly doped region of the first conductivity type between the gate and the source doping region;
wherein no isolation is formed between the gate and the drain doping region.

2. The high-voltage metal-dielectric-semiconductor transistor according to claim 1, wherein the drain doping region is formed in a second well of the first conductivity type

3. The high-voltage metal-dielectric-semiconductor transistor according to claim 1 further comprising a drain lightly doped region of the first conductivity type between the gate and the drain doping region.

4. The high-voltage metal-dielectric-semiconductor transistor according to claim 2 wherein a channel region is defined between the source lightly doped region and the second well.

5. The high-voltage metal-dielectric-semiconductor transistor according to claim 4 further comprising a gate dielectric layer disposed between the gate and the channel region.

6. The high-voltage metal-dielectric-semiconductor transistor according to claim 1 wherein the gate includes two contiguous portions: a first portion and a second portion, and wherein the first portion of the gate has a first concentration of dopants, the second portion, which is proximate to the drain doping region, has a second concentration of dopants.

7. The high-voltage metal-dielectric-semiconductor transistor according to claim 6 wherein the second concentration is lower than the first concentration.

8. The high-voltage metal-dielectric-semiconductor transistor according to claim 1 wherein the gate comprises a sidewall spacer.

9. The high-voltage metal-dielectric-semiconductor transistor according to claim 8 wherein the source lightly doped region is located under the sidewall spacer.

10. The high-voltage metal-dielectric-semiconductor transistor according to claim 8 wherein the drain doping region is not aligned with an edge of the sidewall spacer.

11. The high-voltage metal-dielectric-semiconductor transistor according to claim 4 wherein the channel region comprises a bulk portion of the semiconductor substrate.

12. The high-voltage metal-dielectric-semiconductor transistor according to claim 4 wherein the channel region comprises an intrinsic region located under the gate.

13. A high-voltage metal-dielectric-semiconductor transistor, comprising:
a semiconductor substrate;
a trench isolation region in the semiconductor substrate surrounding an active area;
a gate overlying the active area;
a drain doping region of a first conductivity type in a bulk portion of the semiconductor substrate, wherein the semiconductor substrate is of a second conductivity type;
a drain lightly doped region of the first conductivity type in the bulk portion of the semiconductor substrate between the gate and the drain doping region;
a source doping region of the first conductivity type in a well of the second conductivity type; and
a source lightly doped region of the first conductivity type between the gate and the source doping region;
wherein no isolation is formed between the gate and the drain doping region.

14. A high-voltage metal-dielectric-semiconductor transistor, comprising:
a semiconductor substrate;
a trench isolation region in the semiconductor substrate surrounding an active area;
a gate overlying the active area;
a drain doping region of a first conductivity type in a first well of the first conductivity type, wherein no isolation is formed within the first well, the semiconductor substrate is of a second conductivity type;
a source doping region of the first conductivity type in a second well of the second conductivity type; and
a source lightly doped region of the first conductivity type between the gate and the source doping region.

15. The high-voltage metal-dielectric-semiconductor transistor according to claim 14 wherein a drain lightly doped region of the first conductivity type is disposed in the first well between the gate and the drain doping region.
